(19) United States
(12) Patent Application Publication
(10) Pub. No.: US 2009/0127612 A1
(43) Pub. Date: May 21, 2009

(54) SEMICONDUCTOR DEVICE HAVING A GATE STRUCTURE

(76) Inventors: Weon-Ho PARK, Suwon-si (KR); Byoung-Ho KIM, Suwon-si (KR); Hong-Kook MIN, Yongin-si (KR)

Correspondence Address: F. CHAU & ASSOCIATES, LLC, 130 WOODBURY ROAD, WOODBURY, NY, 11797, US

(21) Appl. No.: 12/265,876

(22) Filed: Nov. 6, 2008

(30) Foreign Application Priority Data
Nov. 15, 2007 (KR) 2007-116790

(51) Int. Cl. H01L 29/788

(52) U.S. Cl. 257/316; 257/E29.3

(57) ABSTRACT

A gate structure in a semiconductor device includes a dielectric layer pattern on a substrate, a floating gate on the dielectric layer pattern, a gate mask on the floating gate, a tunnel insulation layer on the substrate, and a word line on the tunnel insulation layer. The dielectric layer pattern includes a first portion and a second portion having a thickness different from a thickness of the first portion. The floating gate includes a step and tips. The tunnel insulation layer makes contact with a sidewall of the floating gate. The word line extends on a portion of the gate mask.

### CROSS-REFERENCE TO RELATED APPLICATIONS

This application claims priority under 35 U.S.C. §119 to Korean patent Application No. 2007-116790, filed on Nov. 15, 2007, the disclosure of which is hereby incorporated by reference herein in its entirety.

### BACKGROUND

1. Technical Field

Example embodiments relate to a semiconductor device having a gate structure and to a method of manufacturing a semiconductor device having a gate structure. More particularly, example embodiments relate to a semiconductor device including a split gate structure, and to a method of manufacturing a semiconductor device including a split gate structure.

2. Description of the Related Art

A semiconductor device having a flash memory cell has been widely used in various applications such as, for example, in a memory card, a digital camera, a voice recorder, a cellular phone, etc., because data may be electrically stored/eliminated into/from the semiconductor device and the data stored in the semiconductor device may be maintained even though an applied power is off.

Generally, flash memory devices are typically classified as either NAND type flash memory devices or NOR type flash memory devices in accordance with cell array structures thereof. The NAND type flash memory device may have a relatively high degree of integration and a relatively low response speed, whereas the NOR type flash memory device may have a relatively high response speed and a relatively low degree of integration. In the NOR type flash memory device, a plurality of cell transistors are electrically connected to one bit line in parallel, and one of the cell transistors is electrically connected between a source and a drain electrically connected to the bit line. Thus, the NOR type flash memory device may provide an increased cell current and a high response speed.

To improve the programming efficiency of the NOR type flash memory device, an additional transistor (e.g., an additional selection transistor) may be provided between the source and the drain such that one memory cell of the flash memory device is composed of two transistors. When the memory cell includes two transistors, however, the NOR type flash memory device may not have the desired high degree of integration.

Recently, a non-volatile semiconductor device has been developed to include a split gate structure in which a word line having a selection gate and a control gate is provided on an upper face and a sidewall of a floating gate for trapping electrons.

FIG. 1 is a cross-sectional view illustrating a memory cell of a conventional non-volatile semiconductor device.

Referring to FIG. 1, floating gates 14 of a conventional non-volatile memory cell are provided on an active region of a substrate 10 by a predetermined distance. Dielectric layers 12 are interposed between the substrate 10 and the floating gates 14, respectively.

Oxide masks 16 are disposed on the floating gates 14. A tunnel oxide layer 18 is formed on the substrate to cover the oxide masks 16 and sidewalls of the floating gates 14.

Word lines 20 are disposed on the tunnel oxide layer 18. Each of the word lines 20 partially covers each of the floating gates 14. A common source region 22 is formed a portion of the substrate 10 between the floating gates 14. Drain regions 24 are provided at portions of the substrate 10 adjacent to the word lines 20.

As illustrated in FIG. 1, the memory cell of the conventional non-volatile semiconductor device includes a selection transistor I and a memory transistor II. The word line 20 is electrically insulated from the floating gate 14 by the oxide mask 16 and the tunnel oxide layer 18. Channel regions are generated at portions of the substrate 10 under the floating gate 14 and the word line 20. A channel length corresponds to widths of the channel regions between the common source region 22 and the drain region 24.

In the programming process for the memory cell of the conventional non-volatile semiconductor device, a predetermined voltage is generated in the floating gate 14 through coupling phenomena caused by a high voltage applied to the common source region 22. When a predetermined voltage (higher than a threshold voltage of the transistor generated between the word line 20 and the channel region) is applied to the word line 20, the channel region may be formed between the common source region 20 and the drain region 24 so that electrons (e) are injected from the drain region 24 into the floating gate 14 through hot electron injection phenomena, thereby storing data in the memory cell. When the voltage applied to the word line 20 is properly adjusted, an electric field generated at edge portions of the floating gate 14 may be increased such that the programming efficiency of the memory cell may be improved.

In the erasing process for the memory cell, a voltage is applied to the word line 20 while applying predetermined voltages to the common source region 20 and the drain region 24. Hence, the electrons in the floating gate 14 move toward the word line 20 through the tunnel oxide layer 18 by Fowler-Nordheim tunnel phenomena to thereby eliminate the data from the memory cell.

When the memory cell of the semiconductor device has the above-mentioned construction, the semiconductor device may have a size substantially smaller than that of a semiconductor device including an additional transistor between a source region and a drain region. However, electrons may be injected into the floating gate only along a vertical direction in the programming operation of the semiconductor device, so that the semiconductor device may not provide a desired high programming efficiency. Although an electric field generated at the edges of the floating gate may increase so as to improve the programming efficiency, the semiconductor device may have a considerably increased current consumption because a high voltage may be applied to the memory cell in the programming operation.

### SUMMARY

Example embodiments may provide a gate structure of a memory cell in a semiconductor device which improves the programming efficiency thereof.

Example embodiments may provide a method of manufacturing a gate structure of a memory cell in a semiconductor device to improve programming efficiency.

Example embodiments may provide a semiconductor device including a split structure to provide enhanced electrical characteristics and programming efficiency.

Example embodiments may provide a method of manufacturing a semiconductor device including the split gate structure to improve electrical characteristics and programming efficiency.

In accordance with an example embodiment, a gate structure in a semiconductor device is provided. The gate structure in the semiconductor device includes a dielectric layer pattern formed on a substrate, a floating gate formed on the dielectric layer pattern, a gate mask formed on the floating gate, a tunnel insulation layer formed on the substrate, and a word line formed on the tunnel insulation layer. The dielectric layer pattern includes a first portion and a second portion having a thickness different from a thickness of the first portion. The floating gate has a step and tips and the tunnel insulation layer makes contact with a sidewall of the floating gate. The word line extends on a portion of the gate mask.

In example embodiments, the dielectric layer pattern may have a step between the first portion and the second portion.

In example embodiments, a thickness of the first portion and the second portion may be in a range of about 1.0:0.2 to about 1.0:2.0.

In example embodiments, the gate mask may have a step in accordance with the step of the dielectric layer pattern.

In example embodiments, the tunnel insulation layer may have a single layer structure of an oxide film or a multi layer structure of oxide films.

In example embodiments, the tunnel insulation layer may cover the sidewall of the floating gate, a sidewall of the dielectric layer pattern and a sidewall of the gate mask.

In example embodiments, the word line may cover the tunnel insulation layer covering the sidewall of the dielectric layer pattern and the sidewall of the floating gate, and the word line may also cover a portion of the gate mask.

In accordance with example embodiments, a semiconductor device including a split gate structure is provided. The semiconductor device includes a first gate formed on a substrate, a second gate formed on the substrate being separated from the first gate, a common source region formed between the first gate and the second gate, and drain regions formed adjacent to the first and the second gates. The first gate includes a first dielectric layer pattern, a first floating gate, a first gate mask, a first tunnel insulation layer and a first word line. The second gate includes a second dielectric layer pattern, a second floating gate, a second gate mask, a second tunnel insulation layer and a second word line. Each of the first dielectric layer pattern and the second dielectric layer pattern include a first portion and a second portion having a thickness different from that of the first portion. The first tunnel insulation layer and the second tunnel insulation layer make contact with sidewalls of the first floating gate and the second floating gate, respectively.

In example embodiments, the first floating gate and the second floating gate may have steps, respectively. Each of the first dielectric layer pattern and the second dielectric layer pattern may have a step between the first portion and the second portion. Further, the first gate mask and the second gate mask may each have steps in accordance with the steps of the first dielectric layer pattern and the second dielectric layer pattern.

In example embodiments, the semiconductor device may further include a common tunnel insulation layer formed on the common source region and sidewalls of the first floating gate and the second floating gate. A first spacer may be formed on one sidewall of the first word line and a second spacer may be formed on the common tunnel insulation layer positioned on the sidewall of the first floating gate. Further, a third spacer may be formed on the common tunnel insulation layer positioned on the sidewall of the second floating gate, and a fourth spacer may be formed on one sidewall of the second word line.

In example embodiments, the semiconductor device may further include a fifth spacer formed on the other sidewall of the first word line and a sixth spacer formed on the other sidewall of the second word line.

In example embodiments, the first tunnel insulation layer may extend from one of the drain regions to the sidewall of the first floating gate, and the second tunnel insulation layer may extend from the other of the drain regions to the sidewall of the second floating gate.

In accordance with example embodiments, a method of manufacturing a gate structure in a semiconductor device is provided. In the method of manufacturing the gate structure in the semiconductor device, a dielectric layer is formed on a substrate. The dielectric layer includes a first portion and a second portion having a thickness different from a thickness of the first portion. A first conductive layer is formed on the dielectric layer. The first conductive layer has a step. A gate mask is formed on the first conductive layer. A floating gate is formed on the dielectric layer by patterning the first conductive layer using the gate mask. The floating gate includes a step and tips. A dielectric layer pattern is formed on the substrate by patterning the dielectric layer. A tunnel insulation layer is formed on the substrate. The tunnel insulation layer makes contact with a sidewall of the floating gate. A word line is formed on the tunnel insulation layer. The word line extends on a portion of the gate mask.

In the formation of the dielectric layer according to example embodiments, a first preliminary dielectric layer may be formed on the substrate, and then a second preliminary dielectric layer may be formed on a portion of the first preliminary dielectric layer. A thickness ratio between the first preliminary dielectric layer and the second preliminary dielectric layer may be in a range of about 1.0:0.17 to about 1.0:1.5.

In the formation of the dielectric layer according to example embodiments, a preliminary dielectric layer may be formed on the substrate, and the preliminary dielectric layer may be partially removed.

In the formation of the gate mask according to example embodiments, a mask pattern may be formed on the first conductive layer. The mask pattern may expose a portion of the first conductive layer. The exposed portion of the first conductive layer may be oxidized.

In example embodiments, the tunnel insulation layer may be formed by performing at least one oxidation process.

In accordance with example embodiments, a method of manufacturing a semiconductor device including a split gate structure is provided. In the method of manufacturing the semiconductor device including the split gate structure, a dielectric layer is formed on a substrate. The dielectric layer includes a first portion, a second portion and a third portion wherein the second portion has a thickness different from those of the first and the third portions. After a first conductive layer is formed on the dielectric layer, a first mask pattern and a second mask pattern are formed on the first conductive layer. The first and the second mask patterns expose portions of the first conductive layer. A first gate mask and a second gate mask are formed on the exposed portions of the first conductive layer. A first floating gate and a second floating gate are provided by patterning the first conductive layer using the first and the second gate masks. Each of the first floating gate and the second floating gate includes a step. A first dielectric layer pattern and a second dielectric layer pattern are formed on the substrate by patterning the dielectric layer. Each of the first dielectric layer pattern and the second dielectric layer pattern includes a step. A first tunnel insulation layer and a second tunnel insulation layer are formed on the substrate. The first tunnel insulation layer and the second tunnel insulation layer each make contact with sidewalls of the first floating gate and the second floating gate, respectively. A first word line is formed on the first insulation layer and a second word line is formed on the second insulation layer. The first word line and the second word line extend on the first gate mask and the second gate mask, respectively. A common source region is formed at a first portion of the substrate between the first floating gate and the second floating gate. Drain regions are formed at second portions of the substrate adjacent to the first floating gate and the second floating gate.

In example embodiments, the first and the second gate masks may be formed by oxidizing the exposed portions of the first conductive layer.

In example embodiments, a common tunnel insulation layer may be formed on the first portion of the substrate and the sidewalls of the first floating gate and the second floating gate.

In example embodiments, a first spacer may be formed on one sidewall of the first word line, and a second spacer may be formed on a portion of the common tunnel insulation layer formed on the sidewall of the first floating gate. Further, a third spacer may be formed on a portion of the common tunnel insulation layer formed on the sidewall of the second floating gate, and a fourth spacer may be formed on one sidewall of the second word line. A fifth spacer may be formed on the other sidewall of the first word line and a sixth spacer may be formed on the other sidewall of the second word line.

### BRIEF DESCRIPTION OF THE DRAWINGS

Example embodiments can be understood in more detail from the following description taken in conjunction with the accompanying drawings, in which:

FIG. 1 is a cross-sectional view illustrating a memory cell of a conventional non-volatile semiconductor device;

FIG. 2 is a cross-sectional view illustrating a gate structure in a semiconductor device according to example embodiments;

FIG. 3 to 6 are cross-sectional views illustrating a method of manufacturing a semiconductor device having a gate structure in accordance with example embodiments;

FIG. 7 is a cross-sectional view illustrating a memory cell in a semiconductor device in accordance with example embodiments; and

FIGS. 8 to 13 are cross-sectional views illustrating a method of manufacturing a semiconductor device in accordance with example embodiments.

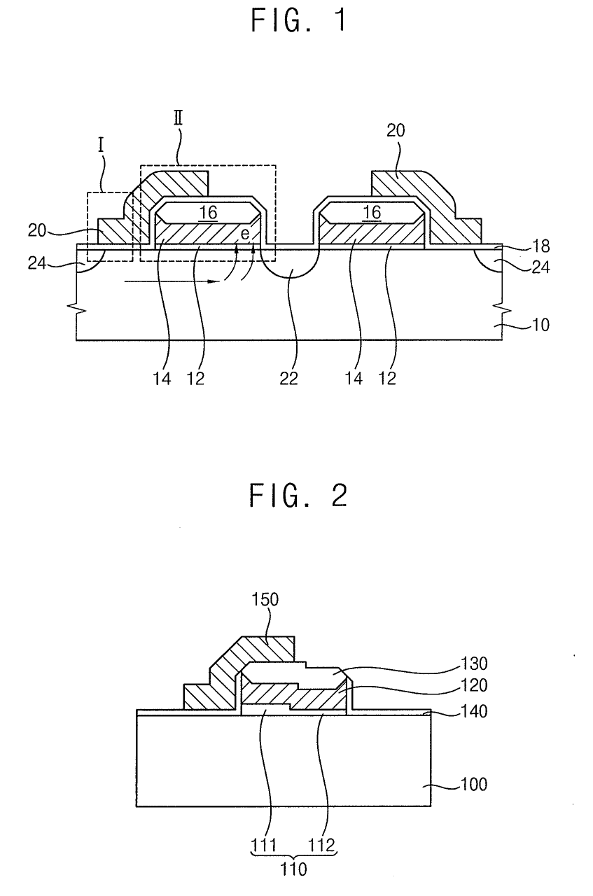

### DESCRIPTION OF EMBODIMENTS

Example embodiments are described more fully hereinafter with reference to the accompanying drawings. The invention may, however, be embodied in many different forms and should not be construed as limited to the example embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like or similar reference numerals refer to like or similar elements throughout. As used herein, the term “and/or” includes any and all combinations of one or more of the associated listed items.

It will be understood that, although the terms first, second, third etc. may be used herein to describe various elements, components, regions, layers, patterns and/or sections, these elements, components, regions, layers, patterns and/or sections should not be limited by these terms. These terms are only used to distinguish one element, component, region, layer pattern or section from another region, layer, pattern or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of illustratively idealized example embodiments (and intermediate structures) of the invention. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 2 is a cross-sectional view illustrating a gate structure in a semiconductor device according to example embodiments. Although FIG. 2 illustrates a gate structure of a memory cell in a non-volatile semiconductor device, the features of the invention may be employed in other memory cells of volatile semiconductor device, for example, a dynamic random access memory (DRAM) device, a static random access memory (SRAM) device, etc.

Referring to FIG. 2, the gate structure in the memory cell includes a dielectric layer pattern 110, a floating gate 120, a gate mask 130, a tunnel insulation layer 140, and a word line 150. In example embodiments, the gate structure may be employed in a split gate type memory cell of a non-volatile semiconductor device.

The dielectric layer pattern 110 is disposed on a substrate 100. The substrate 100 may include a semiconductor substrate, for example, a silicon substrate, a germanium substrate, a silicon-germanium substrate, etc. Alternatively, the substrate 100 may include, for example, a silicon-on-insulator (SOI) substrate or a germanium-on-insulator (GOI) substrate.

In example embodiments, the dielectric layer pattern 110 includes a first portion 111 and a second portion 112. The second portion 112 may have a thickness substantially different from a thickness of the first portion 111. Thus, the dielectric layer pattern 110 may have a step provided between the first portion 111 and the second portion 112. The first portion 111 of the dielectric layer pattern 110 may serve as a gate insulation layer of the gate structure in the memory cell, and the second portion 112 of the dielectric layer pattern 110 may function as a coupling insulation layer of the gate structure in the memory cell.

In example embodiments, the second portion 112 of the dielectric layer pattern 110 may have a thickness substantially smaller than that of the first portion 111 of the dielectric layer pattern 110. For example, the first portion 111 of the dielectric layer pattern 110 may have a relatively thick thickness in a range of about 150 Å to about 450 Å, and the second portion 112 of the dielectric layer pattern 110 may have a relatively thin thickness of about 100 Å to about 300 Å. Hence, a thickness ratio between the first portion 111 and the second portion 112 may be, for example, in a range of about 1.0:0.2 to about 1.0:2.0.

In example embodiments, the dielectric layer pattern 110 may include an oxide such as, for example, silicon oxide. Alternatively, the dielectric layer pattern 110 may include a metal oxide having a dielectric constant substantially larger than that of silicon oxide. Examples of the metal oxide in the dielectric layer pattern 110 may include, but are not limited to, hafnium oxide (HfOx), aluminum oxide (AlOx), zirconium oxide (ZrOx), tantalum oxide (TaOx), etc.

The floating gate 120 is located on the dielectric layer pattern 110. The floating gate 120 may have tips (e.g., shape edges) provided at end portions thereof. As the floating gate 120 is positioned on the dielectric layer pattern 110, the floating gate 120 may also have a step in accordance with the step of the dielectric layer pattern 110. However, the floating gate 120 may have a uniform thickness without a thickness difference thereof. The tips of the floating gate 120 may be protruded along a direction substantially perpendicular to the substrate 100.

In example embodiments, the floating gate 120 may have the step directly on the step of the dielectric layer pattern 110, so that a contact area between the floating gate 120 and the dielectric layer pattern 110 may increase. The floating gate 120 may include, for example, polysilicon, a metal and/or a metal compound. For example, the floating gate 120 may include polysilicon doped with impurities, titanium (Ti), tungsten (W), aluminum (Al), tantalum (Ta), tungsten nitride (WNx), titanium nitride (TiNx), aluminum nitride (AlNx), tantalum nitride (TaNx), etc. These may be used alone or in a mixture thereof. Alternatively, the floating gate 120 may have a polyside structure that includes, for example, a polysilicon film and a metal silicide film formed on the polysilicon film. Here, the metal silicide film may include, for example, tungsten silicide (WSix), titanium silicide (TiSix), cobalt silicide (CoSix), tantalum silicide (TaSix), etc.

The gate mask 130 is positioned on the floating gate 120. The gate mask 130 may electrically insulate the floating gate 120 from the word line 150. Further, the gate mask 130 may serve as an etching mask for forming the dielectric layer pattern 110 and the floating gate 120. In example embodiments, the gate mask 130 may include a material that has an etching selectivity relative to the dielectric layer pattern 110 and the floating gate 120. For example, the gate mask 130 may include a nitride such as silicon nitride. Alternatively, the gate mask 130 may include, for example, an oxynitride such as silicon oxynitride or titanium oxynitride.

As the gate mask 130 is provided on the floating gate 120 having the step and the tips, the gate mask 130 may also include a step and sharp edge portions. That is, the step of the gate mask 130 may be formed directly on the step of the floating gate 120 and the edge portions of the gate mask 130 may be positioned on the tips of the floating gate 120. Each of the edge portions of the gate mask 130 may have a thickness substantially smaller than other portions of the gate mask 130. Further, the sharp edge portions of the gate mask 130 may extend along a direction substantially parallel to the substrate 100.

The tunnel insulation layer 140 is disposed on the substrate 100 to cover sidewalls of the dielectric layer pattern 110, the floating gate 120 and the gate mask 130. Namely, the tunnel insulation layer 140 may be continuously formed from the substrate 100 to the sidewalls of the dielectric layer pattern 110, the floating gate 120 and the gate mask 130. However, the tunnel insulation layer 140 is not formed on the top surface of the gate mask 130. In accordance with the sharp edge portions of the gate mask 130 and the tips of the floating gate 120, the tunnel insulation layer 140 may have sharp tips at end portions thereof.

In example embodiments, the tunnel insulation layer 140 may include an oxide such as, for example, silicon oxide. For example, the tunnel insulation layer 140 may include a thermal oxide film and/or a chemical vapor deposition (CVD) oxide film. Alternatively, the tunnel insulation layer 140 may include, for example, a metal oxide that has a dielectric constant substantially larger than that of silicon oxide. Examples of the metal oxide in the tunnel insulation layer 140 may include but are not limited to zirconium oxide, hafnium oxide, tantalum oxide, aluminum oxide, etc. These may be used alone or in a mixture thereof.

The word line 150 is located on the tunnel insulation layer 140 to partially cover the gate mask 130. Here, the step of the gate mask 130 may be exposed by the word line 150. The word line 150 may be conformally formed along profiles of the tunnel insulation layer 140 and the gate mask 130. In example embodiments, the word line 150 may be partially overlapped with a drain region formed at an upper portion of the substrate 100. Further, the word line 150 may be partially overlapped with gate mask 130 and the tunnel insulation layer 140. The word line 150 may be electrically insulated from the floating gate 120 by the tunnel insulation layer 140 and the gate mask 130. Additionally, the word line 150 may serve as a control gate of the gate structure in the memory cell.

In example embodiments, the word line 150 may include, for example, polysilicon, a metal and/or a metal compound. For example, the word line 150 may include polysilicon doped with impurities, tungsten, tungsten nitride, titanium, titanium nitride, aluminum, aluminum nitride, titanium aluminum nitride, tantalum, tantalum nitride, tungsten silicide, titanium silicide, cobalt silicide, etc. The word line 150 may have, for example, a single layer structure that includes a polysilicon film, a metal film, a metal silicide film or a metal nitride film. Alternatively, the word line 150 may have, for example, a multi layer structure that includes at least two of a polysilicon film, a metal film, a metal silicide film and a metal nitride film. For example, the word line 150 may include a polysilicon film and a metal silicide film formed on the polysilicon film.

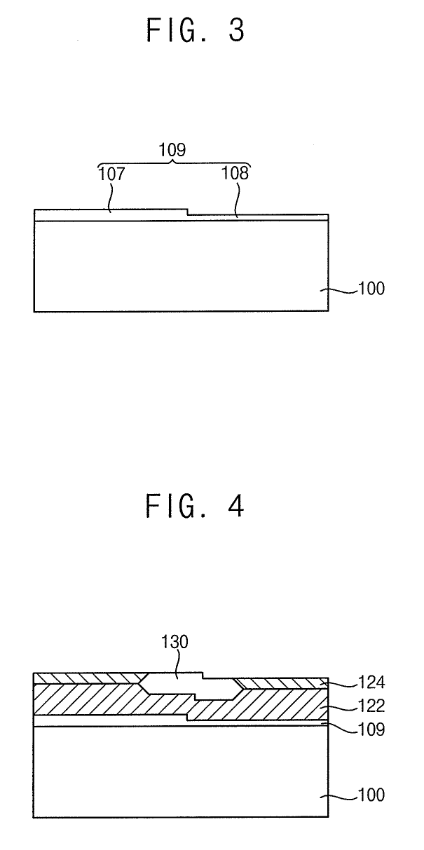

FIGS. 3 to 6 are cross-sectional views illustrating a method of manufacturing a semiconductor device having a gate structure in accordance with example embodiments. FIGS. 3 to 6 illustrate a method of manufacturing a memory cell of a non-volatile semiconductor device, however, the features of the invention may be employed in other memory cells of volatile semiconductor device such as a DRAM device, an SRAM device, etc.

Referring to FIG. 3, a dielectric layer 109 having a first portion 107 and a second portion 108 is formed on a substrate 100. The first portion 107 of the dielectric layer 109 may be relatively thicker than the second portion 108 of the dielectric layer 109. The substrate 100 may include, for example, a semiconductor substrate, an SOI substrate, a GOI substrate, etc.

In the formation of the dielectric layer 109 according to example embodiments, a first preliminary dielectric layer may be formed on the substrate 100. The first preliminary dielectric layer may be formed using, for example, an oxide such as silicon oxide or a metal oxide such as titanium oxide, aluminum oxide, hafnium oxide, zirconium oxide, etc. These may be used alone or in a mixture thereof. Further, the first preliminary dielectric layer may be formed by, for example, a thermal oxidation process, a CVD process, a plasma enhanced chemical vapor deposition (PECVD) process, a high density plasma-chemical vapor deposition (HDP-CVD) process, a sputtering process, an evaporation process, etc. The first preliminary dielectric layer may have a thickness, for example, in a range of about 100 Å to about 300 Å measured from an upper face of the substrate 100. Then, a second preliminary dielectric layer may be formed on a first portion of the first preliminary dielectric layer, so that the dielectric layer 109 having the first and the second portions 107 and 108 may be provided on the substrate 100. The second preliminary dielectric layer may be formed using a material substantially the same or substantially similar to that of the first preliminary dielectric layer. The second preliminary dielectric layer may be relatively thinner than the first preliminary dielectric layer. For example, the second preliminary dielectric layer may have a thickness of about 50 Å to about 150 Å based on an upper face of the first preliminary dielectric layer. Thus, a thickness ratio between the first preliminary dielectric layer and the second preliminary dielectric layer may be, for example, in a range of about 1.0:0.17 to about 1.0:1.5. As a result, a thickness ratio between the first portion 107 and the second portion 108 may be, for example, in a range of about 1.0:0.2 to about 1.0:2.0 because the first portion 107 may have a thickness of, for example, about 150 Å to about 450 Å and the second portion 108 may have a thickness of, for example, about 100 Å to about 300 Å.

In some example embodiments, a preliminary dielectric layer may be formed on the substrate 100, and then a portion of the preliminary dielectric layer may be selectively removed to provide the dielectric layer 109 having the first and the second portions 107 and 108 on the substrate 100. Here, for example, the preliminary dielectric layer may have a thickness of about 150 Å to about 450 Å, and the partially removed portion of the preliminary dielectric layer may have a thickness of about 100 Å to about 300 Å.

Referring to FIG. 4, a first conductive layer 122 is provided on the dielectric layer 109. As the dielectric layer 109 has a step between the first portion 107 and the second portion 108, the first conductive layer 122 may also have a step provided on the step of the dielectric layer 109. The first conductive layer 122 may be formed using, for example, doped polysilicon, metal and/or metal compound. Further, the first conductive layer 122 may be formed by, for example, a CVD process, a PECVD process, a sputtering process, an evaporation process, etc. The first conductive layer 122 may have a thickness of, for example, about 1,000 Å to about 3,000 Å based on an upper face of the dielectric layer 109.

In some example embodiments, the first conductive layer 122 may have a multi layer structure that includes, for example, a polysilicon film and a metal silicide film. Here, the metal silicide film may be formed on the polysilicon film by a silicidation process.

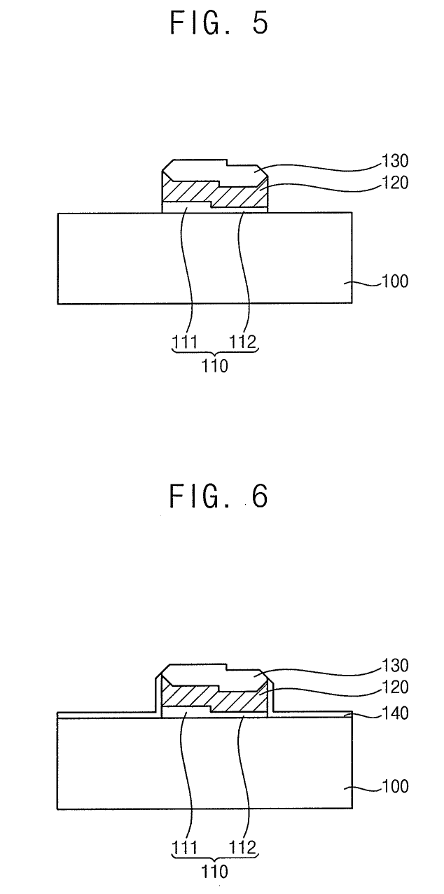

A mask pattern 124 is formed on the first conductive layer 122. The mask pattern 124 may expose a portion of the first conductive layer 122 where a floating gate 120 (see FIG. 5) is defined. The mask pattern 124 may be formed using a material that has an etching selectivity relative to the first conductive layer 122 and the dielectric layer 109. For example, the mask pattern 124 may be formed using a nitride such as silicon nitride.

In example embodiments, impurities may be implanted into the first conductive layer 122 to control a threshold voltage (Vth) of the memory cell. The impurities may be doped into the first conductive layer 122 by an ion implantation process.

A gate mask 130 is formed on the first conductive layer 122. The gate mask 130 may be provided by oxidizing the portion of the first conductive payer 122 exposed through the mask pattern 124. For example, the gate mask 130 may be formed by a local oxidation of silicon (LOCOS) process. The gate mask 130 may have sharp edge portions contacting interfaces between the first conductive layer 122 and the mask pattern 124, respectively. These sharp edge portions of the gate mask 130 may cause tips of the floating gate 120.

In example embodiments, the gate mask 130 is provided on the first conductive layer 122, so that gate mask 130 may also have a step on the step of the first conductive layer 122. In other words, the step of the gate mask 140 may be positioned directly over the step of the dielectric layer 109.

Referring to FIG. 5, the mask pattern 124 is removed from the first conductive layer 122, and then the first conductive layer 122 and the dielectric layer 109 are partially etched to provide the floating gate 120 and a dielectric layer pattern 110 on the substrate 100.

In example embodiments, the floating gate 120 has the tips at edge portions thereof. As described above, the gate mask 130 has the sharp edge portions so that the floating gas 120 also has the tips or sharp edges beneath the sharp edge portions of the gate mask 130. The sharp edge portions of the gate mask 130 may extend along a direction substantially parallel to the substrate 100, whereas the tips of the floating gate 120 may protrude in a direction substantially perpendicular to the substrate 100.

In example embodiments, the dielectric layer 109 may be etched after etching the floating gate 120. Here, the dielectric layer pattern 110 may be formed by, for example, a wet etching process or a self alignment etching process relative to the gate mask 130. According to a structure of the dielectric layer 109, the dielectric layer pattern 110 may have a first portion 111 and a second portion 112 relatively thinner than the first portion 111. Thus, the dielectric layer pattern 110 may also have a step between the first portion 111 and the second portion 112. The first portion 111 of the dielectric layer pattern 110 may serve as a gate insulation layer of the semiconductor device and the second portion 112 of the dielectric layer pattern 110 may function as a coupling insulation layer of the semiconductor device.

Referring to FIG. 6, a tunnel insulation layer 140 is formed on the substrate 100 and sidewalls of the dielectric pattern 110, the floating gate 120 and the gate mask 130. The tunnel insulation layer 140 may be continuously formed from a portion of the substrate 100 to the sidewalls of the dielectric pattern 110, the floating gate 120 and the gate mask 130. The tunnel insulation layer 140 may be formed by, for example, a thermal oxidation process, a CVD process, a sputtering process, etc. When the tunnel insulation layer 140 is provided on the substrate 100, an upper portion of the gate mask 130 is exposed.

In example embodiments, the tunnel insulation layer 140 may have, for example, a single layer structure or a multilayer structure. Here, the tunnel insulation layer 140 having the multi layer structure may be formed by repeatedly performing several thermal oxidation processes. For example, the tunnel insulation layer 140 may include a first tunnel insulation film and a second tunnel insulation film wherein each of the films may have a thickness of about 50 Å to about 150 Å.

A second conductive layer is formed on the tunnel insulation layer 140 and the exposed upper portion of the gate mask 130. The second conductive layer may be formed using, for example, doped polysilicon, metal and/or metal compound. In example embodiments, the second conductive layer may include, for example, a polysilicon film and a metal silicide film. The second conductive layer may be formed by, for example, a CVD process, a PECVD process, a sputtering process, an evaporation process, etc. The second conductive layer may have a thickness of about 500 Å to about 2,000 Å.

After a mask is formed on the second conductive layer, the second conductive layer is etched to form a word line on the tunnel insulation layer 140 and the gate mask 130. The mask may be formed using a photoresist. The word line may have a construction substantially the same as or substantially similar to that of the word line 150 described with reference to FIG. 2. That is, the word line may cover a portion of the gate mask 130 and portions of the tunnel insulation layer 140 positioned on the substrate 100 and the sidewalls of the dielectric layer pattern 110, the floating gate 120 and the gate mask 130.

In example embodiments, the word line may be overlapped with a drain region formed on the substrate 100, and further may be partially overlapped with the gate mask 130. The tunnel insulation layer 140 is formed between the word line and the sidewall of the floating gate 120, so that the floating gate 120 may be electrically insulated from the word line through the tunnel insulation layer 140.

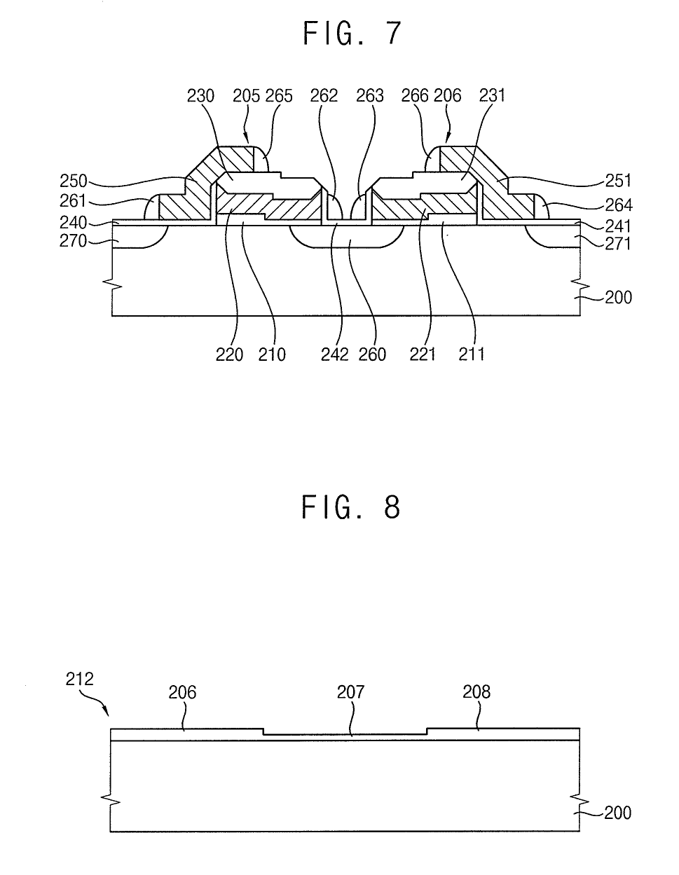

FIG. 7 is a cross-sectional view illustrating a semiconductor device having a split gate structure in accordance with example embodiments.

Referring to FIG. 7, the split gate structure includes a first gate 205 and a second gate 206 provided on a substrate 200. The first gate 205 may be separated from the second gate 206 by a predetermined interval. The first and the second gates 205 and 206 may have substantially symmetrical constructions to each other. A common source region 260 is provided a first portion of the substrate 200 between the first and the second gates 205 and 206. Drain regions 270 and 271 are positioned at second portions of the substrate 200 adjacent to the first and the second gates 205 and 206, respectively.

The first gate 205 includes a first dielectric layer pattern 210, a first floating gate 220, a first gate mask 230, a first tunnel insulation layer 240, and a first word line 250. The first gate 205 further includes a first spacer 261 and a second spacer 262. The second gate 206 includes a second dielectric layer pattern 211, a second floating gate 221, a second gate mask 231, a second tunnel insulation layer 241, and a second word line 251. Additionally, the second gate 206 includes a third spacer 263 and a fourth spacer 264. A common tunnel insulation layer 242 is provided between the first gate 205 and the second gate 206. The common tunnel insulation layer 242 is positioned on the first portion of the substrate 100 and sidewalls of the first and the second gates 105 and 206.

The first and the second dielectric layer patterns 210 and 211 are formed on the substrate 200 by a predetermined distance. The common source region 260 is positioned between the first and the second dielectric layer patterns 210 and 211. Both end portions of the common source region 260 may extend beneath the first and the second dielectric layer patterns 210 and 211, respectively.

Each of the first and the second dielectric layer patterns 210 and 211 has a relatively thick portion and a relatively thin portion. The relatively thick portion may have a thickness of, for example, about 150 Å to about 450 Å and the relatively thin portion may have a thickness of, for example, about 100 Å to about 300 Å. Thus, a step is provided between the relatively thick portion and the relatively thin portion. That is, the first and the second dielectric layers 210 and 211 include steps, respectively. The relatively thin portions of the first and the second dielectric layer patterns 210 and 211 are adjacent to each other. Each of the first and the second dielectric layer patterns 210 and 211 may include, for example, oxide or metal oxide.

As the first and the second dielectric layer patterns 210 and 211 include the relatively thick and the relatively thin portions, the first and the second dielectric layer patterns 210 and 211 have steps between the relatively thick and the relatively thin portions, respectively.

The first floating gate 210 is disposed on the first dielectric layer pattern 210, and the second floating gate 221 is positioned on the second dielectric layer pattern 211. The first and the second floating gates 220 and 211 may each include, for example, an oxide, metal and/or metal compound. The first and the second floating gates 220 and 211 also have steps located on the first and the second dielectric layer patterns 210 and 21, respectively. Further, each of the first and the second floating gates 220 and 221 has tips at edge portions thereof. These tips of the first and the second floating gates 220 and 221 may protrude in a direction substantially perpendicular to the substrate 200.

The first and the second gate masks 230 and 231 respectively formed on the first and the second floating gates 230 and 231. The first and the second gate masks 230 and 231 also have steps on the steps of the first and the second floating gates 220 and 221. The first and the second gate masks 230 and 231 further have sharp edges in accordance with the tips of the first and the second floating gates 220 and 221. The sharp edges of the first and the second gate masks 230 and 231 may extend along a direction substantially parallel to the substrate 200.

The first tunnel insulation layer 240 is formed on the substrate 200 to cover sidewalls of the first dielectric layer pattern 210, the first floating gate 220 and the first gate mask 230. The second tunnel insulation layer 214 is provided on the substrate 200 cover sidewalls of the second dielectric layer pattern 211, the second floating gate 221 and the second gate mask 230. The common tunnel insulation layer 242 is formed on the substrate 200, the sidewalls of the first dielectric layer pattern 210, the first floating gate 220, the first gate mask 230, the second dielectric layer pattern 211, the second floating gate 221 and the second gate mask 230. Each of the first, the second and the common tunnel insulation layers 240, 241 and 242 may include, for example, oxide or metal oxide.

In some example embodiments, one tunnel insulation layer may be divided into three portions. A first portion of the tunnel insulation layer may cover one of the drain regions 270 and the sidewalls of the first dielectric layer pattern 210 and the first floating gate 220. A second portion of the tunnel insulation layer may be formed on the common source region 260 to cover the sidewalls of the first dielectric layer pattern 210, the first floating gate 220, the second dielectric layer pattern 211 and the second floating gate 221. A third portion of the tunnel insulation layer may cover the other of the drain regions 271 and the sidewalls of the second dielectric layer pattern 211 and the second floating gate 221.

The first word line 250 is disposed on a portion of the first gate mask 230 and the first portion of the first tunnel insulation layer 240. The second word line 251 is positioned on a portion of the second gate mask 231 and the third portion of the second tunnel insulation layer 241. The first and the second word lines 250 and 251 include doped polysilicon, metal and/or metal compound. Each of the first and the second gate masks 230 and 231 is exposed by the first and the second word lines 250 and 251.

The first spacer 261 is formed on one of sidewalls of the first word line 250, and the second spacer 262 is provided on the sidewalls of the first dielectric layer pattern 210 and the first floating gate 220. Further, the third spacer 263 is positioned on the sidewalls of the second dielectric layer pattern 211 and the second floating gate 221, and the fourth spacer 264 is formed one of sidewalls of the second word line 251. The first spacer 261 is positioned on a portion of the first tunnel insulation layer 240 over the drain region 270. The common tunnel insulation layer 242 is located between the second spacer 262 and the sidewalls of the first dielectric layer pattern 210 and the first floating gate 220. The common tunnel insulation layer 242 is further located between the third spacer 263 and the sidewalls of the second dielectric layer pattern 211 and the second floating gate 221. The fourth spacer 264 is provided on a portion of the second insulation layer 241 over the drain region 271.

In example embodiments, a fifth spacer 265 is provided on the other of the sidewalls of the first word line 250 and a sixth spacer 266 is formed on the other of the sidewalls of the second word line 250. The fifth and the sixth spacers 265 and 266 are positioned on the first and the second gate masks 230 and 231, respectively.

FIGS. 8 to 13 are cross-sectional views illustrating a method of manufacturing a semiconductor device including a split gate structure in accordance with example embodiments.

Referring to FIG. 8, a substrate 200 having an isolation region and an active region is prepared by an isolation process such as an STI process. That is, an isolation layer is provided on the substrate 200 to define the active region and the isolation region. The isolation layer may be formed using, for example, an oxide such as silicon oxide. The substrate 200 may include, for example, a semiconductor substrate, an SOI substrate, a GOI substrate, etc.

A dielectric layer 212 is formed on the substrate 200. The dielectric layer 212 may be formed using, for example, an oxide or metal oxide. The dielectric layer 212 have a first portion 206, a second portion 207 and a third portion 208. Each of the first and the third portions 206 and 208 may have a thickness substantially larger than that of the second portion 207. Hence, steps may be generated between the first portion 206 and the second portion 207 and the second portion 207 and the third portion 208.

In the formation of the dielectric layer 212 according to example embodiments, a first preliminary dielectric layer may be formed on the substrate 200. The first preliminary dielectric layer may have a thickness of, for example, about 100 Å to about 300 Å based on an upper face of the substrate 200. Then, a second preliminary dielectric layer may be formed on the first preliminary dielectric layer. The second preliminary dielectric layer may have a thickness of, for example, about 50 Å to about 150 Å measured from an upper face of the first preliminary dielectric layer. Here, the first preliminary dielectric layer may have a first portion, a second portion and a third portion, and the second preliminary dielectric layer may be formed on the first and the third portions of the first preliminary dielectric layer. Therefore, the dielectric layer 212 having the first to the third portions 206, 207 and 208 may be provided on the substrate 200. Each of the first and the third portions 206 and 208 may have a thickness of, for example, about 150 Å to about 450 Å whereas the second portion 207 may have a thickness of, for example, 100 Å to about 300 Å. Hence, a thick ratio among the first portion 206, the second portion 207 and the third portion 208 may be, for example, in a range of about 1.0:0.2 to about 2.0:1.0.

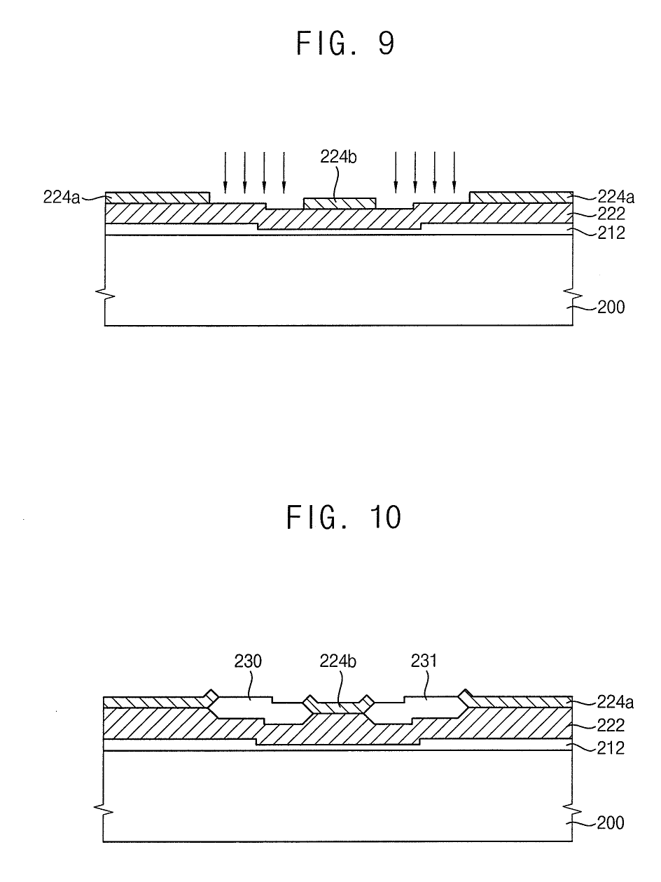

Referring to FIG. 9, a first conductive layer 222 is formed on the dielectric layer 212. As the first conductive layer 222 is positioned on the dielectric layer 212, the first conductive layer 222 may also have steps in accordance with those of the dielectric layer 212. The first conductive layer 222 may be formed using, for example, doped polysilicon, metal and/or metal compound. Further, the first conductive layer 222 may have a thickness of, for example, about 1,000 Å to about 3,000 Å based on an upper face of the dielectric layer 212.

A first mask pattern 224a and a second mask pattern 224b are provided on the first conductive layer 222. After forming the first and the second mask patterns 224a and 224b, portions of the first conductive layer 222 around the steps thereof may be exposed. Each of the first and the second mask patterns 224a and 224b may be formed using, for example, nitride or oxynitride.

As illustrated using arrows, impurities may be doped into the exposed portions of the first conductive layer 222 using the first and the second masks 224a and 224b as implantation masks. The impurities may be doped into the first conductive layer 222 so as to control a threshold voltage (Vth) of the semiconductor device.

Referring to FIG. 10, a first gate mask 230 and a second gate mask 231 are formed on the first conductive layer 222. The first and the second gate masks 230 and 231 may be formed by, for example, an oxidation process such as an LOCOS process. That is, the first and the second gate masks 230 and 231 may be formed by oxidizing the exposed portions of the first conductive layer 222. The first gate mask 230 may be positioned over the step between the first and the second portions 206 and 207 of the dielectric layer 212, and the second gate mask 231 may be formed over the step between the second and the third portions 207 and 208 of the dielectric layer 212.

In example embodiments, the first and the second gate masks 230 and 231 may have sharp edge portions through the oxidation process. The sharp edge portions of the first and the second gate masks 230 and 231 may be protruded along a direction substantially parallel to the substrate 200. When the first and the second gate masks 230 and 231 are provided on the first conductive layer 222, edge portions of the first and the second mask patterns 224a and 224b may be slightly lifted along an upward direction. Further, the sharp edge portions of the first and the second gate masks 230 and 231 may cause tips of a first floating gate 220 and a second floating gate 221 as described below.

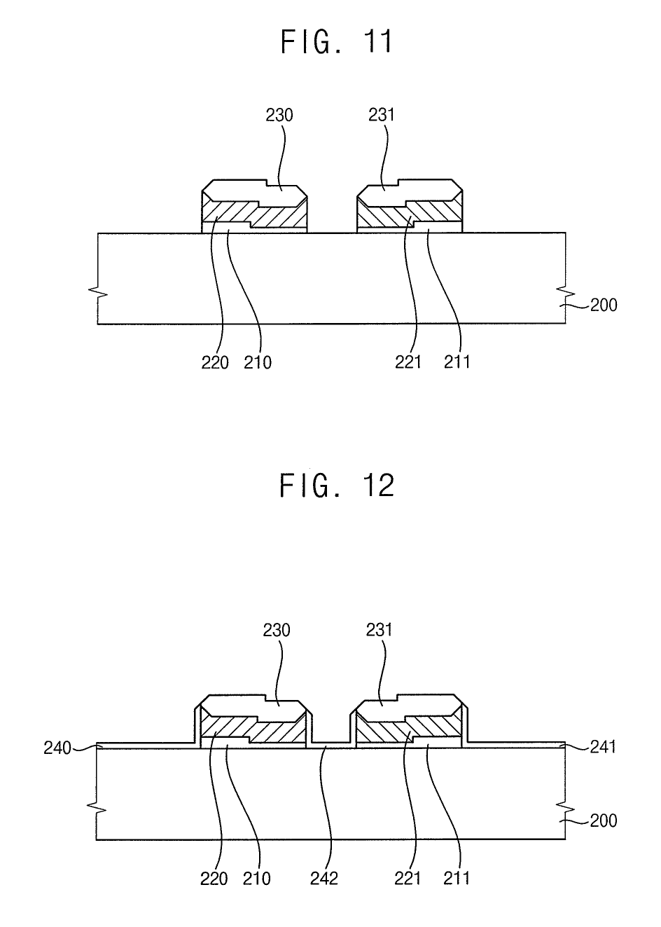

Referring to FIG. 11, the first and the second mask patterns 224a and 224b are removed from the first conductive layer 222. The first and the second mask patterns 224a and 224b may be removed by, for example, a wet etching process. The first conductive layer 222 and the dielectric layer 212 are partially etched to form the first floating gate 220, the second floating gate 221, a first dielectric layer pattern 210 and a second dielectric layer pattern 211.

In example embodiments, the first and the second floating gates 220 and 221 may have tips or sharp edges caused by the sharp edge portions of the first and the second gate masks 230 and 231. The tips of the first and the second floating gates 220 and 221 may protrude in a direction substantially perpendicular to the substrate 200.

The first and the second dielectric layer patterns 210 and 211 are formed by etching the dielectric layer 212 having the first to the third portions 206, 207 and 208. Thus, the first and the second dielectric layer patterns 210 and 211 may have steps, respectively. Further, the first and the second floating gates 220 and 221 also have steps according to the steps of the first and the second dielectric layer patterns 210 and 211.

In example embodiments, the first and the second floating gates 220 and 221 may be formed by, for example a dry etching process, whereas the first and the second dielectric layer patterns 210 and 21 may be provided by, for example, a wet etching process.

Referring to FIG. 12, a first tunnel insulation layer 240, a second tunnel insulation layer 241 and a common tunnel insulation layer 242 are formed on the substrate 200. The common tunnel insulation layer 242 is formed on a first portion of the substrate 200 where a common source region is provided. The first and the second tunnel insulation layers 240 and 241 are positioned on second portions of the substrate 200 at which drain regions are formed. In example embodiments, the first tunnel insulation layer 240, the second tunnel insulation layer 241 and the common tunnel insulation layer 242 may be formed by repeatedly performing oxidation processes. Each of the first, the second and the common tunnel insulation layers 240, 241 and 242 may have, for example, a single layer structure or a multi layer structure.

The first tunnel insulation layer 240 covers sidewalls of the first dielectric layer pattern 210 and the first floating gate 220, and the second tunnel insulation layer 241 is located on sidewalls of the second dielectric layer pattern 211 and the second floating gate 221. The common tunnel insulation layer 242 covers the sidewalls of the first dielectric layer pattern 210, the first floating gate 220, the second dielectric layer pattern 211 and the second floating gate 221.

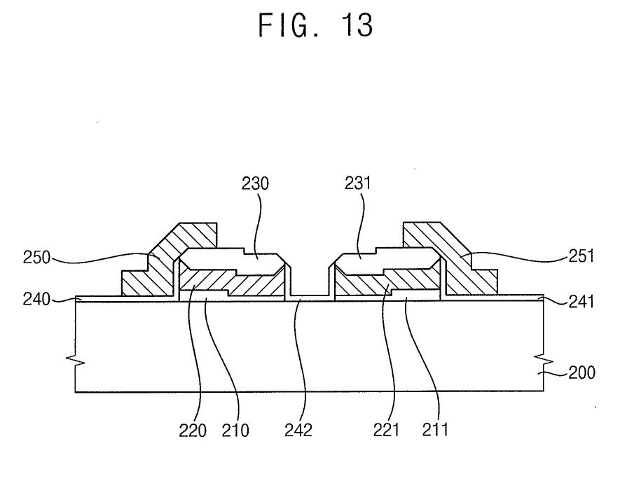

Referring to FIG. 13, a second conductive layer is formed on the substrate 200 to cover the resultant structures. For example, the second conductive layer covers the first tunnel insulation layer 240, the first gate mask 230, the common tunnel insulation layer 242, the second gate mask 231 and the second tunnel insulation layer 241. The second conductive layer may have, for example, a thickness of about 500 Å to about 2,000 Å. The second conductive layer may be formed using, for example, doped polysilicon, metal and/or metal compound. In example embodiments, the second conductive layer may have, for example, a polyside construction including a polysilicon film and a metal silicide film.

After forming a mask on the second conductive layer, the second conductive layer is etched to form a first word line 250 and a second word line 251. The mask may include, for example, a photoresist pattern or a hard mask. The first word line 250 covers portions of the first insulation layer 240 and the first gate mask 230. The second word line 251 is formed on portions of the second tunnel insulation layer 241 and the second gate mask 231. That is, the first and the second gate masks 230 and 231 are partially exposed after forming the first and the second word lines 250 and 251.

The first and the second word lines 250 and 251 may be overlapped with the second portions of the substrate 200 and further may be partially overlapped with the first and the second gate masks 230 and 231. The first and the second word lines 250 and 251 may be electrically insulated from the first and the second floating gates 220 and 221 by the first and the second insulation layers 240 and 241, and the first and the second gate masks 230 and 231. When the first and the second word lines 250 and 251 are formed, a first gate and a second gate are provided on the substrate 200. The first gate includes the first dielectric layer pattern 210, the first floating gate 220, the first tunnel insulation layer 240, a portion of the common tunnel insulation layer 242, the first gate mask 230 and the first word line 250. Further, the second gate includes the second dielectric layer pattern 211, the second floating gate 221, the second tunnel insulation layer 241, a portion of the common tunnel insulation layer 242, the second gate mask 231 and the second word line 251.

First impurities may be doped into the first and the second portions of the substrate 200, so that a preliminary common source region and preliminary drain regions are provided at the first and the second portions of the substrate 200, respectively. Here, the first and the second gates may serve as implantation masks for forming the preliminary common source and drain regions.

After a first spacer, a second spacer, a third spacer, a fourth spacer, a fifth spacer and a six spacer are formed on sidewalls of the first and the second gates, second impurities may be doped into the first and the second portions of the substrate 200. Thus, a common source region and drain regions are provided at the first and the second portions of the substrate 200. Each of the common source and the drain regions may have a lightly doped drain (LDD) structure. The first and the sixth spacers may be positioned at positioned substantially the same as or substantially similar to those of the first to the sixth spacers 261, 262, 263, 264, 265 and 266 described with reference to FIG. 7.

According to example embodiments, a memory cell of a semiconductor device having a gate structure or a split gate structure may have an improved programming efficiency because a floating gate may extend adjacent to a channel region. Additionally, the memory cell may have a reduced current consumption as an applied voltage in a programming operation thereof may be lowered. Furthermore, a dielectric layer pattern and the floating gate may have steps without additional processes to increase a contact area between the dielectric layer pattern and the floating gate, such that the memory cell may provide improved electrical characteristics through simplified manufacturing processes, as well as reduced manufacturing costs and manufacturing time.

Having described example embodiments, it is further noted that it is readily apparent to those of reasonable skill in the art that various modifications may be made without departing from the spirit and scope of the invention which is defined by the metes and bounds of the appended claims.

What is claimed is:

1. A gate structure in a semiconductor device, comprising:
a dielectric layer pattern formed on a substrate, the dielectric layer pattern including a first portion and a second portion having a thickness different from a thickness of the first portion;
a floating gate formed on the dielectric layer pattern, the floating gate including a step and tips;
a gate mask formed on the floating gate;
a tunnel insulation layer formed on the substrate, the tunnel insulation layer making contact with a sidewall of the floating gate; and
a word line formed on the tunnel insulation layer, the word line extending on a portion of the gate mask.

2. The gate structure of claim 1, wherein the dielectric layer pattern has a step between the first portion and the second portion.

3. The gate structure of claim 2, wherein a thickness of the first portion and the second portion is in a range of about 1.0:0.2 to about 1.0:2.0.

4. The gate structure of claim 2, wherein the gate mask has a step in accordance with the step of the dielectric layer pattern.

5. The gate structure of claim 1, wherein the tunnel insulation layer has a single layer structure of an oxide film or a multi layer structure of oxide films.

6. The gate structure of claim 1, wherein the tunnel insulation layer covers the sidewall of the floating gate, a sidewall of the dielectric layer pattern and a sidewall of the gate mask.

7. The gate structure of claim 6, wherein the word line covers the tunnel insulation layer on the sidewalls of the dielectric layer pattern and the floating gate, and a portion of the gate mask.

8. A semiconductor device including a split gate structure, comprising:
a first gate formed on a substrate, the first gate comprising a first dielectric layer pattern, a first floating gate, a first gate mask, a first tunnel insulation layer and a first word line;
a second gate formed on the substrate being separated from the first gate, the second gate comprising a second dielectric layer pattern, a second floating gate, a second gate mask, a second tunnel insulation layer and a second word line;
a common source region formed between the first gate and the second gate; and
drain regions formed adjacent to the first and the second gates,
wherein each of the first and the second dielectric layer patterns includes a first portion and a second portion having a thickness different from that of the first portion, and the first and the second tunnel insulation layers make contact with sidewalls of the first and the second floating gates, respectively.

9. The semiconductor device of claim 8, wherein the first and the second floating gates have steps, respectively.

10. The semiconductor device of claim 9, wherein each of the first and the second dielectric layer patterns has a step between the first portion and the second portion.

11. The semiconductor device of claim 10, wherein the first and the second gate masks have steps in accordance with the steps of the first and the second dielectric layer patterns.

12. The semiconductor device of claim 8, further comprising a common tunnel insulation layer formed on the common source region and sidewalls of the first and the second floating gates.

13. The semiconductor device of claim 12, further comprising:
a first spacer formed on one sidewall of the first word line;
a second spacer formed on the common tunnel insulation layer positioned on the sidewall of the first floating gate;
a third spacer formed on the common tunnel insulation layer positioned on the sidewall of the second floating gate; and
a fourth spacer formed on one sidewall of the second word line.

14. The semiconductor device of claim 13, further comprising:
a fifth spacer formed on the other sidewall of the first word line: and
a sixth spacer formed on the other sidewall of the second word line.

15. The semiconductor device of claim 8, wherein the first tunnel insulation layer extends from one of the drain regions to the sidewall of the first floating gate, and the second tunnel insulation layer extends from the other of the drain regions to the sidewall of the second floating gate.
